(19) United States
(12) Patent Application Publication
(10) Pub. No.: US 2017/0179182 A1
(43) Pub. Date: Jun. 22, 2017

(54) SEMICONDUCTOR PACKAGE AND METHOD OF FABRICATING THE SAME

(71) Applicant: SAMSUNG ELECTRONICS CO., LTD., Suwon-si (KR)

(72) Inventor: Hyunsu JUN, Seongnam-si (KR)

(21) Appl. No.: 15/379,531

(22) Filed: Dec. 15, 2016

(30) Foreign Application Priority Data
Dec. 18, 2015 (KR) 10-2015-0181874

(51) Int. Cl. H01L 27/146

(52) U.S. Cl. CPC H01L 27/14634; H01L 27/14618; H01L 27/14643; H01L 27/1469

(57) ABSTRACT

A semiconductor package is disclosed. The semiconductor package a circuit substrate, a semiconductor chip mounted on and electrically connected to the circuit substrate, an optoelectronic chip mounted on the semiconductor chip, and an adhesive part interposed between the semiconductor chip and optoelectronic chip.

### CROSS-REFERENCE TO RELATED APPLICATION

Korean Patent Application No. 10-2015-0181874, filed on Dec. 18, 2015, in the Korean Intellectual Property Office, and entitled: Semiconductor Package and Method of Fabricating the Same, is incorporated by reference herein in its entirety.

### BACKGROUND

1. Field

The present disclosure relates to a semiconductor package, and in particular, to a semiconductor package, in which an image sensor chip and a semiconductor chip are provided, and a method of fabricating the same.

2. Description of the Related Art

Image sensors, such as CCD or CMOS image sensors, are variously being used for electronic products, such as mobile phones, digital cameras, optical mice, security cameras, biometric devices, and so forth. Due to an increasing demand for small and multifunctional electronic products, a semiconductor package should be prepared to have an image sensor with improved technical properties (e.g., small size, high density, low power, multifunctional, high signal-processing speed, high reliability, low cost, and clear image quality).

### SUMMARY

According to some embodiments, a semiconductor package may include a circuit substrate, a semiconductor chip mounted on and electrically connected to the circuit substrate, an optoelectronic chip mounted on the semiconductor chip, and an adhesive part interposed between the semiconductor chip and the optoelectronic chip.

According to some embodiments, a semiconductor package may include a circuit substrate, a first chip mounted on the circuit substrate, a second chip mounted on the first chip, the second chip being larger than the first chip, and an adhesive part interposed between the first chip and the second chip. The first chip may include at least one of a memory chip or a logic chip, and the second chip may include an optoelectronic device.

According to some embodiments, a method of fabricating a semiconductor package may include providing a circuit substrate, mounting a semiconductor chip on the circuit substrate, mounting an optoelectronic chip on the semiconductor chip, electrically connecting the optoelectronic chip to the circuit substrate, and encapsulating the semiconductor chip and the optoelectronic chip on the circuit substrate. The mounting of the semiconductor chip on the circuit substrate may include mounting the semiconductor chip in a flip-chip manner.

According to some embodiments, a semiconductor package may include a circuit substrate having a first substrate surface and a second substrate surface spaced apart along a first direction, a first chip having a first chip surface and a second chip surface spaced apart along the first direction, the second chip surface of the first chip being mounted on the first substrate surface of the circuit substrate, the second chip surface of the first chip being electrically connected to the first substrate surface of the circuit substrate, and a second chip having a third chip surface and a fourth chip surface spaced apart along the first direction, the fourth chip surface of the second chip being secured to the second chip surface of the first chip, the second chip being larger than the first chip in at least a second direction, orthogonal to the first direction, the second chip being electrically connected to the first substrate surface of the circuit substrate, wherein the first chip includes at least one of a memory chip or a logic chip, and the second chip includes an optoelectronic device.

### BRIEF DESCRIPTION OF THE DRAWINGS

Features will become apparent to those of skill in the art by describing in detail exemplary embodiments with reference to the attached drawings in which:

FIG. 1A illustrates a plan view of a semiconductor package according to some embodiments.

FIG. 1B illustrates a sectional view taken along line I-I′ of FIG. 1A.

FIG. 2 illustrates a flow chart of a method of fabricating the semiconductor package of FIG. 1.

FIGS. 3A through 3D illustrate sectional views of stages in a method of fabricating a semiconductor package, according to some embodiments.

FIG. 4 illustrates an example of a semiconductor package according to some embodiments.

FIG. 5 illustrates an example of a semiconductor package according to some embodiments.

FIG. 6 illustrates an example of a semiconductor package according to some embodiments.

FIG. 7 illustrates an example of a semiconductor package according to some embodiments.

FIG. 8 illustrates an example of a semiconductor package according to some embodiments.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

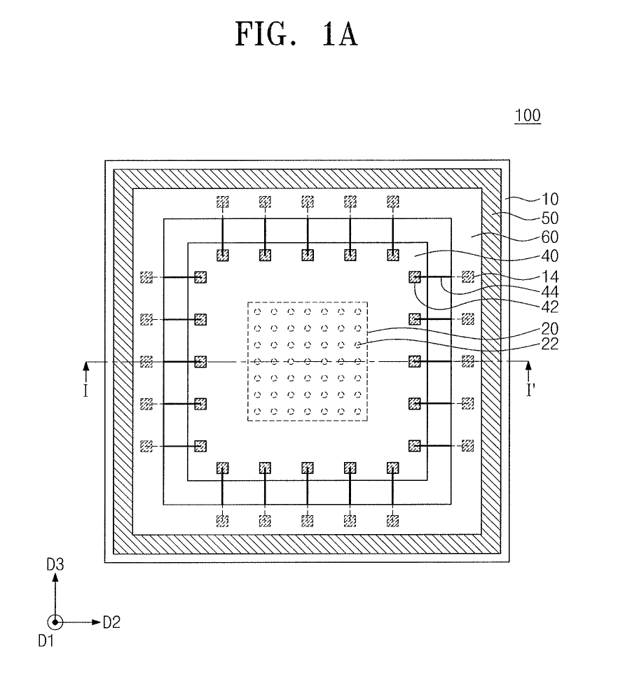

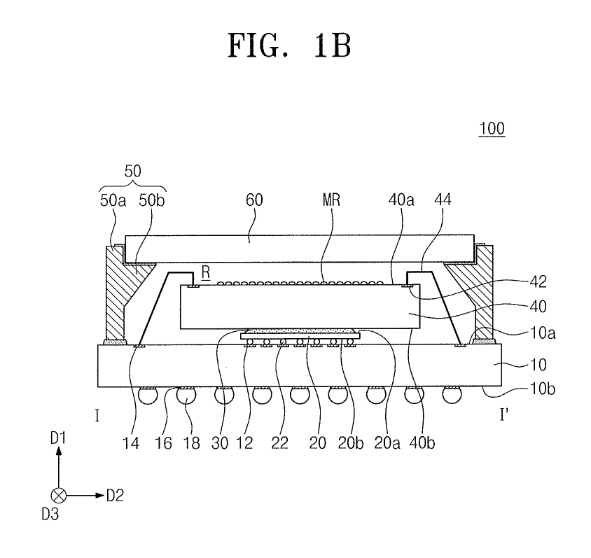

FIG. 1A is a plan view illustrating a semiconductor package 100 according to some embodiments, and FIG. 1B is a sectional view taken along line I-I′ of FIG. 1A. Referring to FIGS. 1A and 1B, the semiconductor package 100 may include a circuit substrate 10, a semiconductor chip 20 mounted on the circuit substrate 10, an image sensor chip 40 mounted on the semiconductor chip 20, an adhesive part 30 interposed between the semiconductor chip 20 and the image sensor chip 40, a transparent cover 60 provided over the image sensor chip 40, and a holder 50 connecting the transparent cover 60 to the circuit substrate 10.

The circuit substrate 10 may have a first substrate surface 10a and a second substrate surface 10b facing each other, e.g., separated from each other along a first direction D1. For example, the first and second substrate surfaces 10a and 10b may be top and bottom surfaces of the circuit substrate 10. First terminals 12 and second terminals 14 may be provided on the first substrate surface 10a of the circuit substrate 10. Third terminals 16 may be provided on the second substrate surface 10b of the circuit substrate 10, and outer solder balls 18 may be attached to the third terminals 16, respectively. The outer solder balls 18 may be electrically connected to an external device (not shown). The circuit substrate 10 may include insulating layers (e.g., include plastic materials or ceramics) and/or conductive vias and conductive patterns interposed between the insulating layers. In some embodiments, the circuit substrate 10 may be a printed circuit board (PCB). The first and second terminals 12 and 14 of the circuit substrate 10 may be electrically connected to each other.

The semiconductor chip 20 may be mounted on the circuit substrate 10. The semiconductor chip may have a first chip surface 20a and a second chip surface 20b separated along the first direction D1. The semiconductor chip 20 may be mounted on the circuit substrate 10 in a flip-chip manner. For example, each of the solder balls 22 may be provided to be in contact with a corresponding one of the first terminals 12. Accordingly, the semiconductor chip 20 and the circuit substrate 10 may be electrically connected to each other, e.g., the first substrate surface 10a and the second chip surface 20b may be electrically connected. The semiconductor chip 20 may include at least one of a memory device, a logic device, a digital signal process integrated circuit, an application specific integrated circuit, and a driver. In some embodiments, the semiconductor chip 20 may be or include a dynamic random access memory (DRAM) chip. The semiconductor chip 20 may be smaller than the image sensor chip 40, e.g., in second and third directions D2, D3 orthogonal to the first direction D1, e.g., in all dimensions.

The adhesive part 30 may be interposed between the semiconductor chip 20 and the image sensor chip 40. The adhesive part 30 may be formed of or include an insulating adhesive material. As an example, the adhesive part 30 may include an epoxy resin.

The image sensor chip 40 may be mounted on the semiconductor chip 20. The image sensor chip 40 may have a first chip surface 40a and a second chip surface 40b separated along the first direction D1. The image sensor chip 40 may be attached to the semiconductor chip 20 by the adhesive part 30, e.g., the second chip surface 40b of the image sensor chip 40 may be secured to the first chip surface 20a of the semiconductor chip 20 using the adhesive part 30. The image sensor chip 40 may include a micro-sensor array MR, fourth terminals 42, and bonding wires 44. The micro-sensor array MR and the fourth terminals 42 may be provided on a top surface of the image sensor chip 40. For example, the micro-sensor array MR may be provided on a center region of the image sensor chip 40, and the fourth terminals 42 may be provided on an edge region of the image sensor chip 40. The image sensor chip 40 may include a plurality of photoelectric conversion devices (not shown), each of which is configured to generate electric charges from an incident light, and here, the incident light may be incident into the photoelectric conversion devices through the micro-sensor array MR. Each of the bonding wires 44 may be provided to electrically connect the image sensor chip 40 to the circuit substrate 10. For example, each of the bonding wires 44 may be provided to connect each of the fourth terminals 42 to a corresponding one of the second terminals 14. The bonding wires 44 may be formed of or include a metallic material (e.g., gold (Au)). Accordingly, the image sensor chip 40 and the circuit substrate 10 may be electrically connected to each other, e.g., the first substrate surface 10a and the first chip surface 40a may be electrically connected.

The holder 50 may be configured to support the transparent cover 60 and to fix a position of the transparent cover 60 relative to the circuit substrate 10, e.g., spaced apart from the circuit substrate along the first direction D1. In some embodiments, the holder 50 may be provided on an edge region of the circuit substrate 10. The semiconductor chip 20 and the image sensor chip 40 may be provided in an internal space R defined by the holder 50. The holder 50 may be opaque to help with stray light. The holder 50 may have a first portion 50a extending in the first direction to provide a predefined separation along the first direction D1 between the circuit substrate 10 and the transparent cover 60. The holder 50 may include a second portion 50b extending in a second direction D2, orthogonal to the first direction DE to support the transparent cover 60. The transparent cover 60 may be provided over the image sensor chip 40. In some embodiments, the transparent cover 60 may be provided spaced apart from the image sensor chip 40.

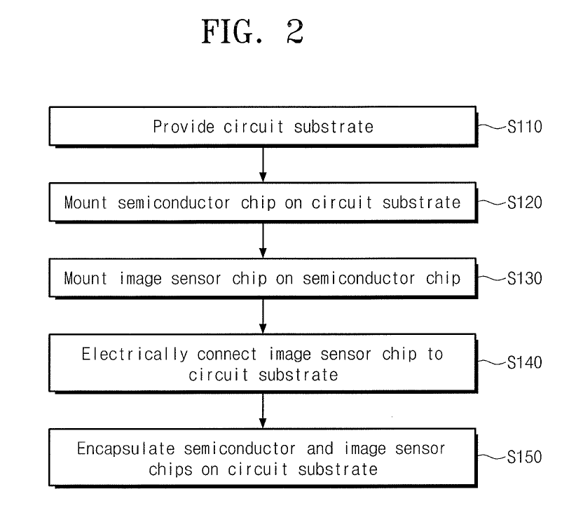

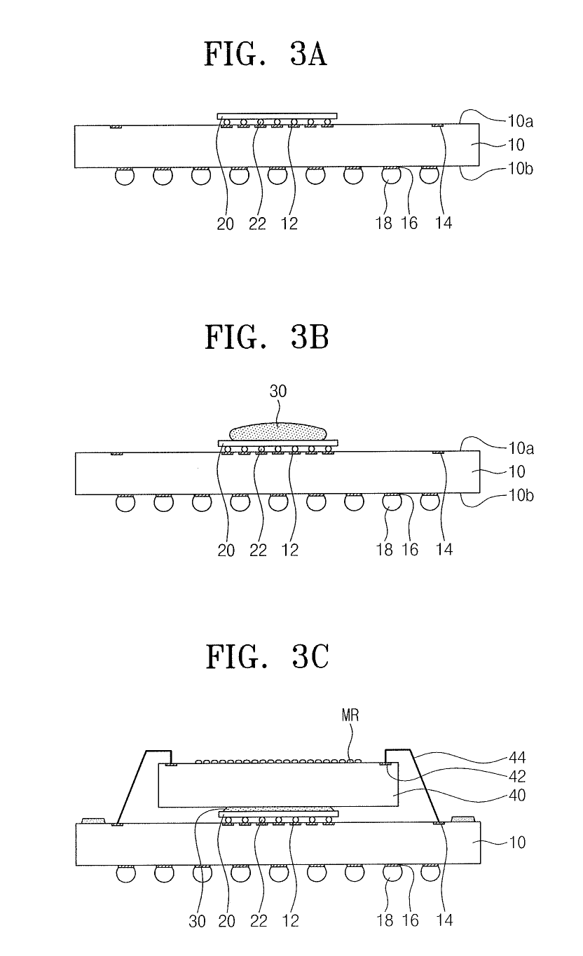

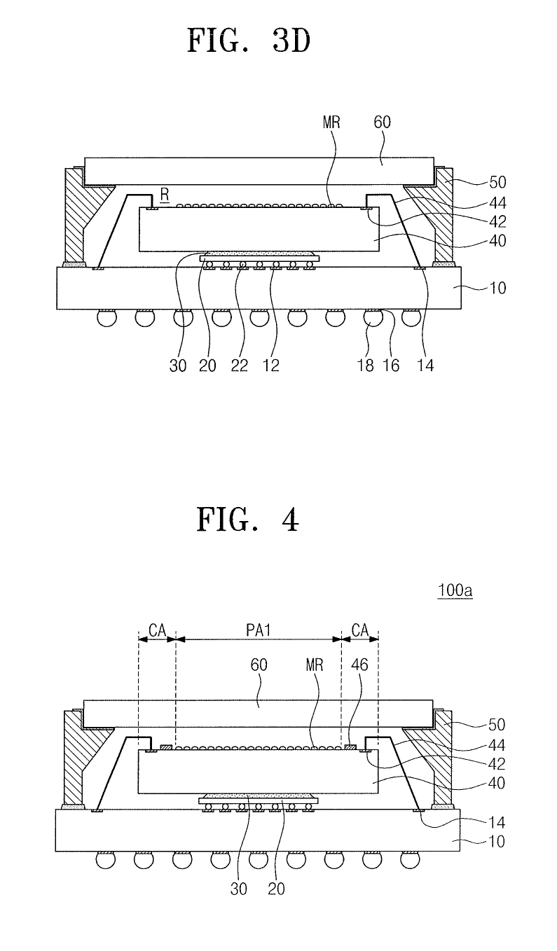

FIG. 2 is a flow chart illustrating a method of fabricating the semiconductor package 100 of FIG. 1. FIGS. 3A through 3D are sectional views illustrating stages in a method of fabricating the semiconductor package 100, according to some embodiments. Hereinafter, the method of fabricating the semiconductor package 100 will be described with reference to FIGS. 2 through 3D.

Referring to FIGS. 2 and 3A, the circuit substrate 10 may be provided (in S110). The first terminals 12 and the second terminals 14 may be provided on the top surface 10a of the circuit substrate 10. Next, the semiconductor chip 20 may be mounted on the circuit substrate 10 (in S120). The semiconductor chip 20 may be mounted, in a flip-chip manner, on the circuit substrate 10 through the solder balls 22. Each of the solder balls 22 may be formed to be in contact with a corresponding one of the first terminals 12. The semiconductor chip 20 may include at least one of a memory device, a logic device, a digital signal process integrated circuit, an application specific integrated circuit, and a driver. In some embodiments, the semiconductor chip 20 may be or include a dynamic random access memory (DRAM) chip.

Referring to FIGS. 2, 3B, and 3C, the image sensor chip 40 may be mounted on the semiconductor chip 20 (in S130). The adhesive part 30 may be interposed between the semiconductor chip 20 and the image sensor chip 40. The image sensor chip 40 may have a size or area larger than that of the semiconductor chip 20. Since the adhesive part 30 is coated on the semiconductor chip 20, whose size is smaller than that of the image sensor chip 40, it is possible to easily control an area of a region to be coated with the adhesive part 30. This may make it possible to attach the image sensor chip 40 to the semiconductor chip 20 with a small amount of the adhesive part 30. Thereafter, the image sensor chip 40 may be electrically connected to the circuit substrate 10 (in S140). For example, the bonding wires 44 may be used to connect the fourth terminals 42 to the second terminals 14, respectively.

Referring to FIGS. 2 and 3D, the semiconductor and image sensor chips 20 and 40 on the circuit substrate 10 may be packaged (in S150). For example, the holder 50 may be provided on or attached to the edge region of the circuit substrate 10, and the transparent cover 60 may be attached or connected to the holder 50. The transparent cover 60 may be disposed over the image sensor chip 40 and may have an area or size larger than that of the micro-sensor array MR of the image sensor chip 40.

According to some embodiments, not only the image sensor chip 40, but also the semiconductor chip 20 may be provided in each semiconductor package 100. In particular, since the semiconductor chip 20 is mounted on the circuit substrate 10 and the image sensor chip 40 is mounted on the semiconductor chip 20, it is possible to reduce a total size, or an area, of the semiconductor package. In contrast, when only the image sensor chip 40 is provided in the semiconductor package 100, an additional package for the semiconductor chip 20 may be separately provided. In addition, since the semiconductor chip 20 is mounted in the flip-chip bonding manner on the circuit substrate 10 and the semiconductor and image sensor chips 20 and 40 are attached to each other by the adhesive part 30, embodiments may be applied to the case that the semiconductor chip 20 and the image sensor chip 40 have different foot-prints from each other. Furthermore, since the image sensor chip 40 is mounted on the semiconductor chip 20 whose size is smaller than the image sensor chip 40, it is possible to easily control an area of a region to be coated with the adhesive part 30 (e.g., coverage of the adhesive part 30). Although the semiconductor chip 20 generates a larger amount of heat compared with the image sensor chip 40, since the semiconductor chip 20 is provided adjacent to the circuit substrate 10, it is possible to improve heat dissipation characteristics of the semiconductor package.

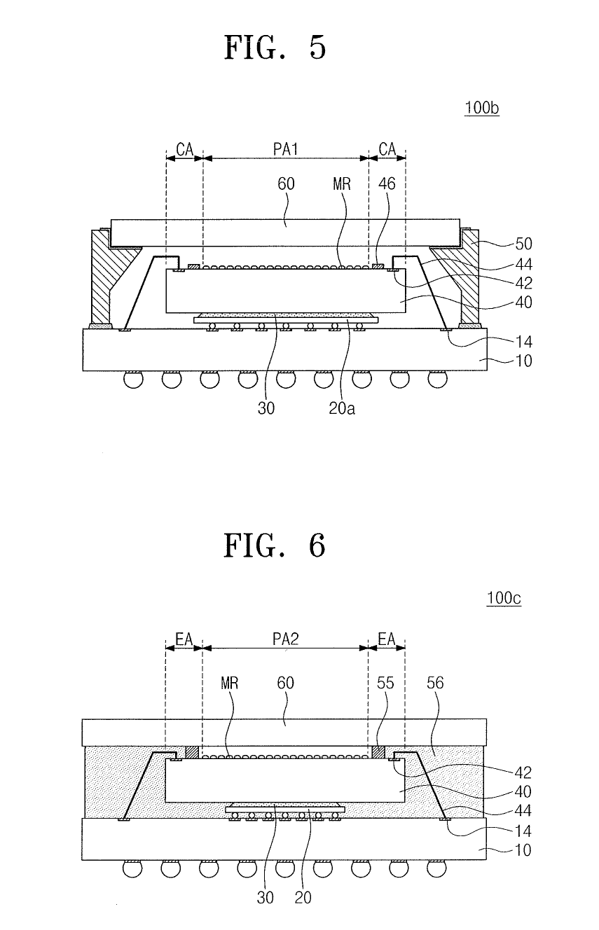

FIG. 4 illustrates a semiconductor package 100a according to some embodiments. FIG. 5 illustrates a semiconductor package 100b according to some embodiments. In the following description of the semiconductor packages 100a and 100b of FIGS. 4 and 5, an element previously described with reference to FIGS. 1A through 3D may be identified by a similar or identical reference number without repeating an overlapping description thereof.

Referring to FIG. 4, the image sensor chip 40 may include a first pixel region PA1 and a circuit region CA. The first pixel region PA1 may be a center region of the image sensor chip 40 and may include the micro-sensor array MR. The circuit region CA may be a region surrounding the first pixel region PA1 and may include the fourth terminals 42 and an integrated circuit 46. The integrated circuit 46 may be a logic circuit. When viewed in a plan view, the semiconductor chip 20 may overlap the first pixel region PA1, e.g., the first pixel region PA1 may completely overlap the semiconductor chip 20 in the first direction D1. As shown in FIG. 4, the semiconductor chip 20 may not overlap the circuit region CA, when viewed in a plan view, e.g., in the first direction D1. In certain embodiments, as shown in FIG. 5, the semiconductor chip 20a may overlap with at least a portion of the circuit region CA, when viewed in a plan view.

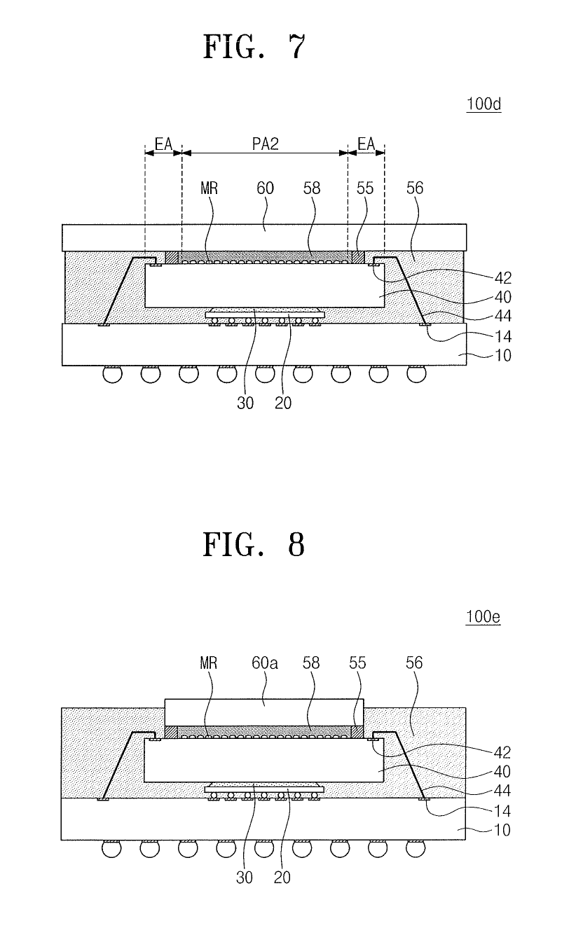

FIG. 6 illustrates a semiconductor package 100c according to some embodiments. FIG. 7 illustrates a semiconductor package 100d according to some embodiments. FIG. 8 illustrates a semiconductor package 100e according to some embodiments. In the following description of the semiconductor packages 100c, 100d, and 100e of FIGS. 6 and 8, an element previously described with reference to FIGS. 1A through 3D may be identified by a similar or identical reference number without repeating an overlapping description thereof.

Referring to FIG. 6, the holder 50 of FIG. 1B may not be provided in the semiconductor package 100c. Instead, the semiconductor package 100c may further include an adhesive pattern 55 and a molding part 56. The adhesive pattern 55 may be provided to attach the transparent cover 60 to the image sensor chip 40. The adhesive pattern 55 may be provided on an edge region of the image sensor chip 40. As an example, the adhesive pattern 55 may be a ring-shaped element that is provided on the edge region of the image sensor chip 40. In some embodiments, the adhesive pattern 55 may include an epoxy resin material containing fillers. Here, the image sensor chip 40 may include a second pixel region PA2 and an edge region EA. The second pixel region PA2 may be a center region of the image sensor chip 40 and may include the micro-sensor array MR. The edge region EA may be a region enclosing the second pixel region PA2 and may include the fourth terminals 42 and the adhesive pattern 55. The molding part 56 may be provided to fill a gap region between the circuit substrate 10 and the transparent cover 60. The molding part 56 may include a thermosetting polymer. The molding part 56 may be provided to hermetically seal the gap region between the circuit substrate 10 and the transparent cover 60, except for a space between the second pixel region PA2 and the transparent cover 60 enclosed by the adhesive pattern 55.

Alternatively, as shown in FIG. 7, the semiconductor package 100d may further include a filling material 58, which is provided between the second pixel region PA2 and the transparent cover 60 to fill the space enclosed by the adhesive pattern 55. The filling material 58 may be transparent. For example, the filling material 58 may be formed of or include at least one of transparent polymeric materials (e.g., polymethyl methacrylate (PMMA), polycarbonate (PC), transparent thermosetting epoxy, and transparent ABS). In certain embodiments, as shown in FIG. 8, the semiconductor package 100e may include a transparent cover 60a having a size or area smaller than the circuit substrate 10. For example, the size of the transparent cover 60a may be equal to or larger than that of a region for the micro-sensor array MR and may be smaller than that of the circuit substrate 10.

According to some embodiments, not only an image sensor chip but also a semiconductor chip may be stacked in each semiconductor package, and thus, it is possible to reduce a total size of the semiconductor package. In contrast, in the case where only the image sensor chip is provided in the semiconductor package, it may be necessary to separately provide an additional package for the semiconductor chip. The inventive concept may be applied to the case that the semiconductor chip and the image sensor chip have different foot-prints from each other. Furthermore, since the image sensor chip is mounted on the semiconductor chip whose size is smaller than the image sensor chip, it is possible to easily control an area of a region to be coated with an adhesive part (e.g., coverage of the adhesive part). In addition, although the semiconductor chip generates a larger amount of heat compared with the image sensor chip, since the semiconductor chip is provided adjacent to a circuit substrate, it is possible to improve heat dissipation characteristics of the semiconductor package.

Example embodiments have been disclosed herein, and although specific terms are employed, they are used and are to be interpreted in a generic and descriptive sense only and not for purpose of limitation. For example, while embodiments herein refer to an image sensor chip, other types of optoelectronic chips, e.g., light emitting chips, may be used in accordance with embodiments. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

1. A semiconductor package, comprising:
a circuit substrate;
a semiconductor chip mounted on and electrically connected to the circuit substrate;
an optoelectronic chip mounted on the semiconductor chip; and
an adhesive part interposed between the semiconductor chip and optoelectronic chip.

2. The semiconductor package as claimed in claim 1, wherein the optoelectronic chip comprises:
a first pixel region at a center region of the optoelectronic chip; and
a circuit region enclosing the first pixel region and including an integrated circuit,
wherein the first pixel region overlaps the semiconductor chip, when viewed in a plan view.

3. The semiconductor package as claimed in claim 2, wherein the circuit region is spaced apart from the semiconductor chip, when viewed in a plan view.

4. The semiconductor package as claimed in claim 2, wherein at least a portion of the circuit region overlaps the semiconductor chip, when viewed in a plan view.

5. The semiconductor package as claimed in claim 1, wherein the semiconductor chip comprises a memory device.

6. The semiconductor package as claimed in claim 1, wherein the semiconductor chip comprises a logic device.

7. The semiconductor package as claimed in claim 1, wherein
the optoelectronic chip is electrically connected to the circuit substrate.

8. The semiconductor package as claimed in claim 1, wherein the semiconductor chip is smaller than the optoelectronic chip.

9. The semiconductor package as claimed in claim 1, further comprising:
a transparent cover on the optoelectronic chip; and
an adhesive pattern interposed between the optoelectronic chip and the transparent cover.

10. The semiconductor package as claimed in claim 9, wherein optoelectronic chip comprises:
a second pixel region at a center region of the optoelectronic chip; and
an edge region enclosing the second pixel region,
wherein the adhesive pattern is provided on the edge region of the optoelectronic chip, and
the edge region is spaced apart from the semiconductor chip, when viewed in a plan view.

11. The semiconductor package as claimed in claim 1, further comprising:
a transparent cover provided on the optoelectronic chip; and
a holder provided on an edge region of the circuit substrate and connected to the transparent cover to define an internal space, in which the semiconductor chip and the optoelectronic chip are provided.

12. A semiconductor package, comprising:
a circuit substrate;
a first chip mounted on the circuit substrate;
a second chip mounted on the first chip, the second chip being larger than the first chip; and
an adhesive interposed between the first chip and the second chip,
wherein the first chip includes at least one of a memory chip or a logic chip, and the second chip includes an optoelectronic device.

13. The semiconductor package as claimed in claim 12, wherein the second chip comprises:
a first pixel region at a center region of the second chip; and
a circuit region enclosing the first pixel region,
wherein the first pixel region overlaps the first chip, when viewed in a plan view.

14. The semiconductor package as claimed in claim 13, wherein the circuit region is spaced apart from the first chip, when viewed in a plan view.

15. The semiconductor package as claimed in claim 13, wherein at least a portion of the circuit region overlaps the first chip, when viewed in a plan view.

16. The semiconductor package as claimed in claim 12, further comprising:
a transparent cover above the second chip; and
an adhesive pattern interposed between the second chip and the transparent cover.

17. The semiconductor package as claimed in claim 16, wherein the second chip comprises:
a second pixel region at a center region of the second chip; and
an edge region enclosing the second pixel region,
wherein the adhesive pattern is provided on the edge region of the second chip, and
the edge region is spaced apart from the first chip, when viewed in a plan view.

18. The semiconductor package as claimed in claim 12, wherein the circuit substrate comprises first terminals, and
the first chip comprises solder balls, each of which is in contact with a corresponding one of the first terminals.

19. The semiconductor package as claimed in claim 12, wherein the circuit substrate comprises second terminals,
the second chip comprises third terminals, and
the semiconductor package further comprises bonding wires connecting the second terminals to the third terminals, respectively.

20. The semiconductor package as claimed in claim 12, wherein the first chip is a dynamic random access memory (DRAM) chip.

21-23. (canceled)
